(19) United States
(12) Patent Application Publication
(10) Pub. No.: US 2025/0098326 A1
(43) Pub. Date: Mar. 20, 2025

(54) AREA-OPTIMIZED CELLS FOR LOW POWER TECHNOLOGY NODES

(71) Applicant: ATI Technologies ULC, Thornhill (CA)

(72) Inventor: Ioan CORDOS, Ontario (CA)

(73) Assignee: ATI Technologies ULC, Thornhill, ON (CA)

(21) Appl. No.: 18/369,451

(22) Filed: Sep. 18, 2023

(51) Int. Cl. H01L 27/02; H01L 27/118

(52) U.S. Cl. CPC H10D 89/10; H10D 84/903

(57) ABSTRACT

Embodiments herein describe identifying voltage potentials in separate cells that can be combined so that a dummy gate between or in the cells can be removed. For example, some combinational logic cells such as XOR gates, XNOR gates, and half-adders are formed from coupling two combinational cells in sequence. Typically, a dummy gate is placed between those cells since they have different voltage potentials. However, if the cells have the same voltage potentials, then the dummy gate can be removed and the cells can overlap by sharing a net. This can reduce the overall size of the cell.

### TECHNICAL FIELD

Examples of the present disclosure generally relate to removing dummy gates between (or in) cells by sharing voltage potentials.

### BACKGROUND

An exclusive OR/NOR (XOR and XNOR) cell is a logic standard cell widely used in digital logic. XOR and XNOR can be implemented using a multiplexer style or using combinational logic. For example, an XOR cell can be implemented with a NOR cell and a AND-OR-INVERTER (AOI) cell connected in series. An XNOR cell is complementary logic to XOR and can be implemented using a NAND cell and an OR-AND-INVERTER (OAI) cell connected in series.

In a low power process (e.g., a 3 nm process), with only four horizontal tracks for internal routing, a classic implementation for the two cells (e.g., NOR+AOI or NAND+OAI) results in a 7 contacted poly pitch (CPP) wide cell (e.g., 7 poly sticks or gates). The two cells are separated by a dummy gate because the two cells use different voltage potentials. This dummy gate adds 1 CPP of width to the XOR and XNOR cells.

### SUMMARY

One embodiment described herein is an integrated circuit that includes at least one of an XOR or XNOR circuit comprising at least two cells. Moreover, the two cells overlap such that each of the two cells share at least one net and there is no dummy gate between or in either of the two cells.

One embodiment described herein is a system that includes an IC that includes at least one of an XOR or XNOR circuit comprising at least two cells where the at least two cells overlap and there is no dummy gate between or in either of the two cells. The system also includes a memory communicatively coupled to the IC.

One embodiment described herein is a method that includes providing a layout of an XOR or XNOR circuit comprising multiple cells with at least one shared net and fabricating an IC that includes the XOR or XNOR circuit using the layout and a 3 nm process or smaller.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a schematic of a XOR gate, according to an example.

FIG. 2 illustrates a layout of an XOR gate with a dummy gate between a NOR cell and an AOI cell, according to an example.

FIG. 3 illustrates a layout of an XOR gate with overlapping NOR and AOI cells, according to an example.

FIG. 4 illustrates a layout of an XNOR gate with overlapping NAND and OAI cells, according to an example.

FIG. 5 illustrates a half-adder circuit, according to an example.

FIG. 6 illustrates a half-adder circuit, according to an example.

FIG. 7 illustrates a layout of a half-adder cell with a dummy gate between an inverter cell and a XOR cell, according to an example.

FIG. 8 illustrates a layout of an half-adder cell with overlapping inverter and XOR cells, according to an example.

FIG. 9 is a method for fabricating an integrated circuit, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the embodiments herein or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Embodiments herein describe identifying voltage potentials in separate cells that can be combined so that a dummy gate between (or in) the cells can be removed. For example, some combinational logic cells such as XOR gates, XNOR gates, and half-adders are formed from coupling two combinational cells in sequence. Typically, a dummy gate is place between (or in) those cells since they have different voltage potentials. However, if the cells have the same voltage potentials, then the dummy gate can be removed and the cells can overlap. This can remove at least 1 CPP which reduces the overall width of the cell. For example, removing a dummy gate between cells, a 7 CPP XOR or XNOR gate can bfe shrunk to a 6 CPP XOR or XNOR gate (e.g., a reduction of approximately 48 nm) or a 10 CPP half adder circuit can be shrunk to 9 CPP.

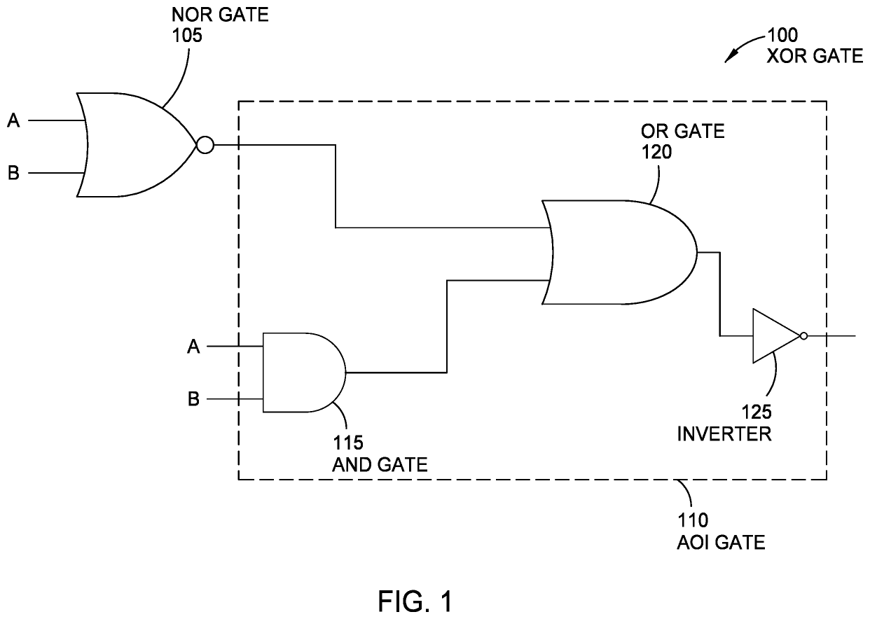

FIG. 1 illustrates a schematic of a XOR gate 100, according to an example. In this example, the XOR gate 100 is implemented using combinational logic that includes a NOR gate 105 coupled to an AOI gate 110. As shown, the AOI gate 110 includes an AND gate 115, OR gate 120, and an inverter 125 (or NOT gate). For instance, the NOR gate 105 and the AOI gate 110 can be coupled in series.

In one embodiment, the NOR gate 105 is a NOR2 gate indicating it has two inputs, and the AOI gate 110 is a AO121 gate which means the AND gate 115 has two inputs and the OR gate 120 has one input.

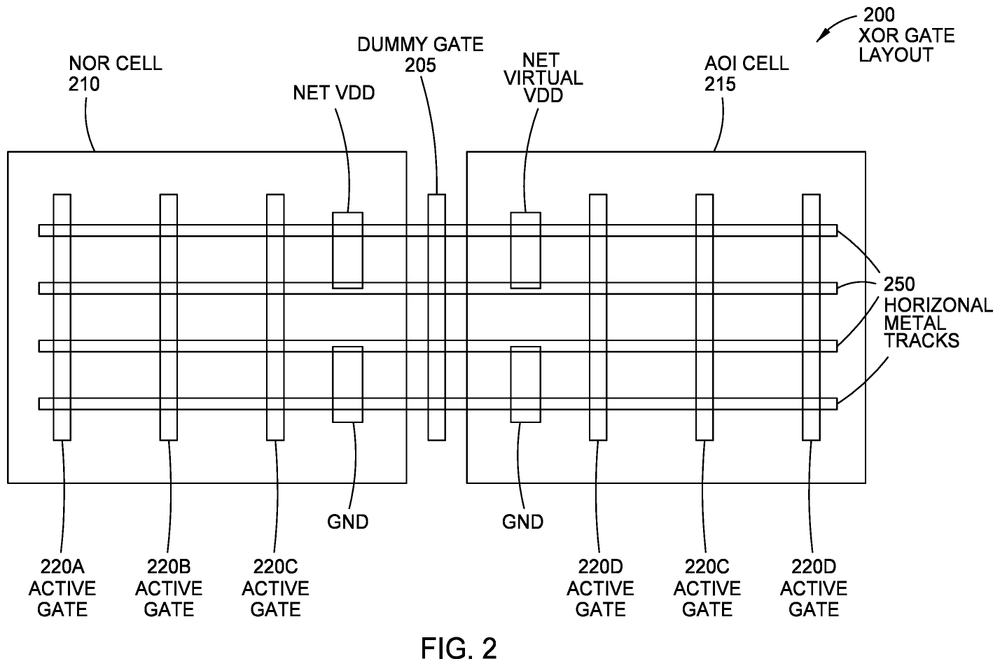

FIG. 2 illustrates a layout 200 of an XOR gate with a dummy gate between a NOR cell 210 and an AOI cell 215, according to an example. That is, the XOR gate layout 200 illustrates a layout on a semiconductor device that implements the XOR gate. For example, the layout 200 can be used to generate masks that fabricate the XOR gate into an integrated circuit (IC). Thus, unlike FIG. 1 which is a schematic of the XOR gate, FIG. 2 illustrates components in a physical layout of the XOR gate in an IC. This layout 200 can include multiple layers in the IC.

For clarity, the XOR gate layout 200 does not show every layer and component in the XOR gate. For example, the layout 200 does not show silicon channels (for forming transistors), contacts, diffusion layers, and various other components that one of ordinary skill in the art will recognize would be part of a layout for a XOR gate. Instead, the layout 200 illustrates that the NOR cell 210 and the AOI cell 215 include active gates 220 that are separated by a dummy gate 205. In one embodiment, the dummy gate 205 may be formed at the same time as the active gates 220 (e.g., using the same fabrication steps) but may not be connected to a voltage source (e.g., is inactive). In contrast, the active gates 220 may extend over channels and diffusions areas to form multiple transistors which are interconnected to form the logic of the NOR cell 210 and the AOI cell 215 as shown in FIG. 1.

In one embodiment, the pitch (or spacing) between the active gates 220 and the dummy gate 205 is fixed. This pitch is often referred to as the CPP. In current technologies, 1 CPP (e.g., the pitch between two adjacent active gates 220, or the pitch between the dummy gate 205 and an adjacent active gate 220) is approximately 48 nm. For example, for 3 nm processes, the pitch between two adjacent active gates 220 is approximately 48 nm while in 7 nm processes, the pitch is approximately 58 nm. In one embodiment, the embodiments described herein are implemented using 3 nm processes and smaller, and thus, the pitch between two adjacent active gates 220 is approximately 50 nm or less.

Because the XOR gate layout 200 has six active gates 220 and one dummy gate 205, it has a width of 7 CPP. While the term CPP is used, the gates 220 and 205 can be made out of other materials besides polysilicon, such as metals.

Moreover, each row in the layout 200 can include four horizontal metal tracks 250 that extend perpendicular to the active gates 220. That is, while FIG. 2 illustrates one row, the layout for an entire IC may include multiple rows, where each of those rows has four metal tracks 250. In the 3 nm process (and potentially smaller processes), the gates, drains, and sources of the transistors forming the XOR/XNOR gate can coupled to any of the at least four metal tracks. In contrast, while the 7 nm process also includes four metal tracks per row, the gates 220 are able to connect to only the two middle tracks of the four metal tracks 250. Stated differently, the gates 220 in a 3 nm process can connect to any of the metal tracks 250 in a row while in the 7 nm process the gates 220 can couple to only the two middle tracks.

In this example, the NOR cell 210 also includes two nets (or metal contacts) labeled NET VDD and GND (ground). The AOI cell 215 also includes two nets: NET VIRTUAL VDD and GND. Notably, the NOR cell 210 and the AOI cell 215 may include more nets than these, but they are not shown for clarity.

Typically, it is assumed that NET VDD and NET VIRTUAL VDD are different voltages. As such, the dummy gate 205 is used to separate the two different voltage potentials in the NOR cell 210 and the AOI cell 215. That is, the dummy gate 205 insulates these two nets from each other. However, the dummy gate 205 also insulates the GND net in the NOR cell 210 and the GND net in the AOI cell 215, even though these nets are the same voltage potential. Thus, it is assumed that the dummy gate 205 is required since the NET VDD and the NET VIRTUAL VDD are different voltages.

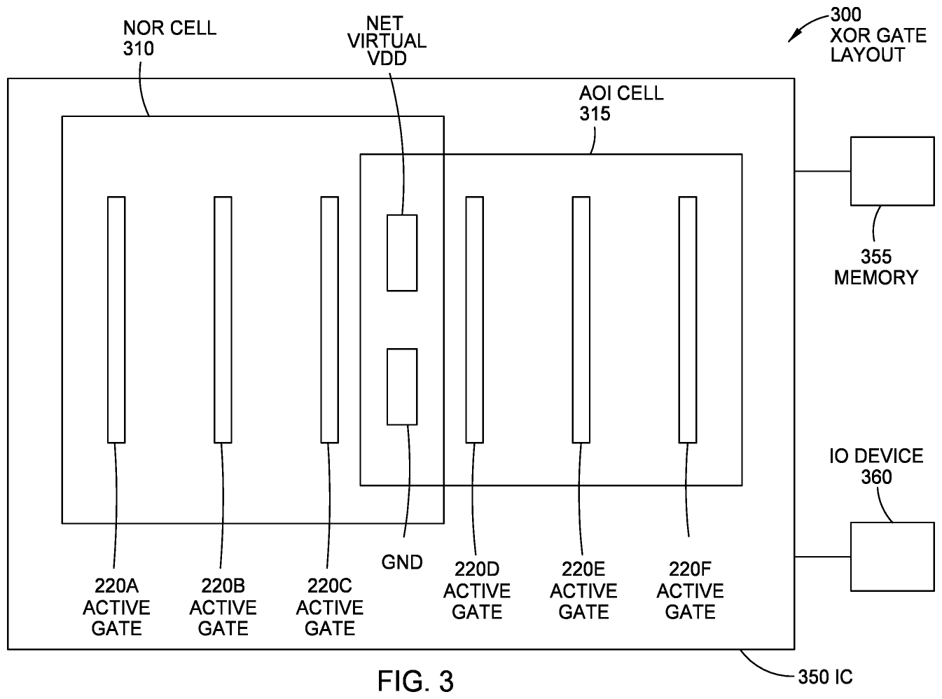

However, in some implementations, the NET VDD and the NET VIRTUAL VDD are the same voltage, and thus, can be considered as the same net. For example, when the two inputs into the XOR gate are low (e.g., logical 0), the net VDD is at NET VIRTUAL VDD. As a result, the NET VIRTUAL VDD is functionally equivalent as the NET VDD. Thus, the nets on both sides of the dummy gate 205 are functionally the same. This knowledge can then be used to optimize the XOR gate layout as shown in FIG. 3.

FIG. 3 illustrates a layout 300 of an XOR gate with overlapping NOR and AOI cells, according to an example. Compared to FIG. 2, in FIG. 3 the dummy gate has been removed. Moreover, instead of the XOR gate having two cells that are separated by the dummy gate, the layout 300 has an NOR cell 310 that overlaps with the AOI cell 315. In this case, the NET VIRTUAL VDD and the GND are two nets that are shared by both the NOR cell 310 and the AOI cell 315, which causes these cells to overlap. Stated differently, the NET VIRTUAL VDD and GND are in both the NOR cell 310 and the AOI cell 315, when in FIG. 2 these cells had their own metal contacts.

By removing the dummy cell and sharing the nets, the width of the XOR gate layout 300 can be smaller than the XOR gate layout 200 in FIG. 2. Specifically, the XOR gate layout 300 has only six active gates 220, which means it has a width of 6 CPP instead of the 7 CPP width of the XOR gate layout 200 in FIG. 2. Thus, by combining the two pairs of nets in FIG. 2 into one pair of nets in FIG. 3, the dummy gate can be removed and the physical layout 300 of the XOR gate in the IC can be reduced by 1 CPP. This advantageously saves area in the IC.

In one embodiment, the layout 300 is used in a 3 nm process, and may also apply to smaller (future) process nodes. Advantageously, there is no dummy gate (or dummy device) in either of the NOR cell 310 or the AOI cell 315 in FIG. 3. Other larger processes, such as the 7 nm process, can also benefit from the knowledge that NET VDD and the NET VIRTUAL VDD are the same voltage. That is, a XOR gate in the 7 nm process may also have a NOR cell and an AOI cell with a VDD net and a VIRTUAL VDD net that can be combined so that these cells overlap. This can reduce the size of the XOR gate (e.g., from 8CPP to 7CPP). However, due to technology design rules, a XOR gate formed using the 7 nm process still includes a dummy gate (e.g., a dummy device). For example, even after combining the nets, there may be a dummy gate or a dummy device in the AOI cell (e.g., an output net) of the XOR gate formed using a 7 nm process. Dummy gates or devices on the output net add parasitic capacitance, impacting cell performance, but are still included in order to satisfy design rules associated with the 7 nm process. Thus, the 7 nm process may be unable to achieve the ideal 6CPP width that can be achieved in the layout 300 using a 3 nm process where there are no dummy gates or dummy devices in any of the cells forming the XOR gate.

FIG. 3 also illustrates that the XOR gate layout 300 can be implemented in an IC 350. The IC 350 can be coupled to other circuitry, ICs, or devices. In this example, the IC 350 is coupled to a memory 355 (e.g., DRAM, SRAM, High Bandwidth Memory (HBM), etc.). For example, the memory 355 may be another IC which is part of the same package (or system) as the IC 350. Also, the IC 350 is shown as being connected to an IO device 360. For example, the IC 350 may be desired in applications where lower power and small ICs are advantageous, such as an entertainment system in a vehicle. The IO device 360 may be a touch screen, voice sensor, or other type of IO device disposed in the vehicle which is communicatively coupled to the IC 350. Thus, the IC 350 can be part of different systems that include other ICs (e.g., the memory 355) and/or devices (e.g., the IO device 360).

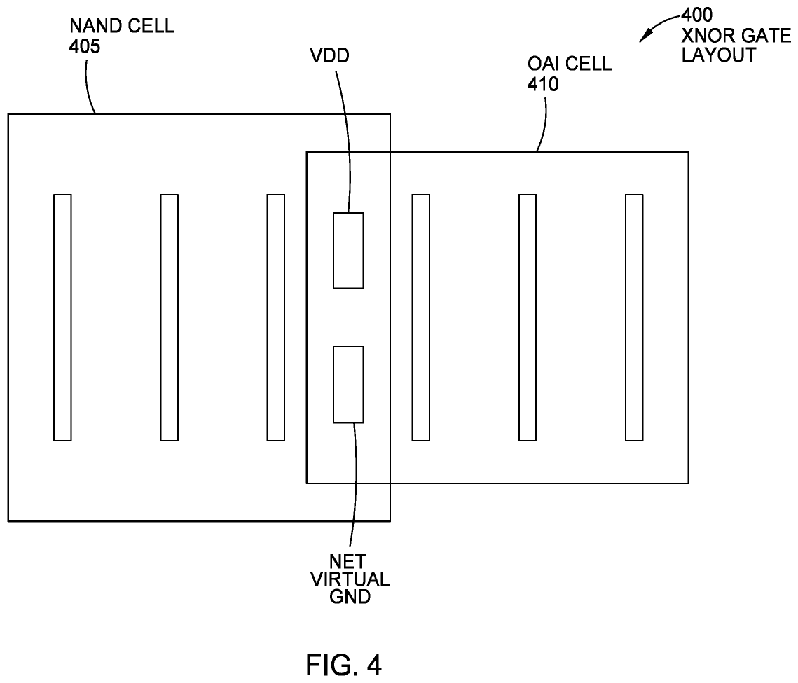

FIG. 4 illustrates a layout 400 of an XNOR gate with overlapping NAND and OAI cells, according to an example. Instead of a XOR gate as discussed in FIGS. 1-3, FIG. 4 is directed towards a XNOR gate. FIG. 4 illustrates that the same technique discussed above for removing a dummy gate can be applied to the layout 400 of a XNOR gate.

As discussed above, a XNOR gate can be formed by coupling a NAND gate in series with a OAI gate. This is represented in the layout 400 where a NAND cell 405 is arranged next to a OAI cell 410. Typically, a dummy gate would be disposed between these cells because of the different voltage potentials between these cells. However, it has been found that pairs of voltages in the cells are functionally equivalent, and thus can be combined to form one pair of nets—i.e., GND and NET VIRTUAL GND. As a result, the dummy gate can be removed from the layout 400.

As shown, the NAND cell 405 overlaps with the OAI cell 410 since these cells share the nets GND and NET VIRTUAL GND. That is, the metal contacts corresponding to these nets are part of both the NAND cell 405 and the OAI cell 410. Because the dummy gate has been removed, the width of the of the layout 400 can be reduced by 1 CPP relative to a XNOR gate layout 400 with a dummy gate. For example, overlapping the NAND cell 405 and the OAI cell 410 can reduce the layout from 7 CPP to 6 CPP (e.g., a reduction of approximately 50 nm). Because XOR and XNOR gates are common components in many IC designs, this can result in significant area savings in an IC.

In one embodiment, the layout 400 is used in a 3 nm process, and may also apply to smaller (future) process nodes. Advantageously, there is no dummy gate (or dummy device) in either of the NAND cell 405 or the OAI cell 410. As above, other larger processes, such as the 7 nm process, can also benefit from the knowledge that two nets in the two cells are the same voltage. That is, a XNOR gate in the 7 nm process may also have a NAND cell and an OAI cell with nets that can be combined so that these cells overlap. This can reduce the size of the XNOR gate from, e.g., 8CPP to 7CPP. However, due to technology design rules, a XNOR gate formed using the 7 nm process can still include a dummy gate (e.g., a dummy device) in one of the cells, which negatively impacts performance (due to parasitic capacitance) and increases the size of the layout, but is required due to design rules associated with the 7 nm process. Thus, the 7 nm process may be unable to achieve the ideal 6CPP width that can be achieved in the layout 400 using a 3 nm process where there are no dummy gates or dummy devices in any of the cells forming the XNOR gate.

Although not shown, the XNOR gate layout 400 can also be implemented in an IC (like in FIG. 3). This IC can be part of a system (e.g., a package) that includes other ICs and devices.

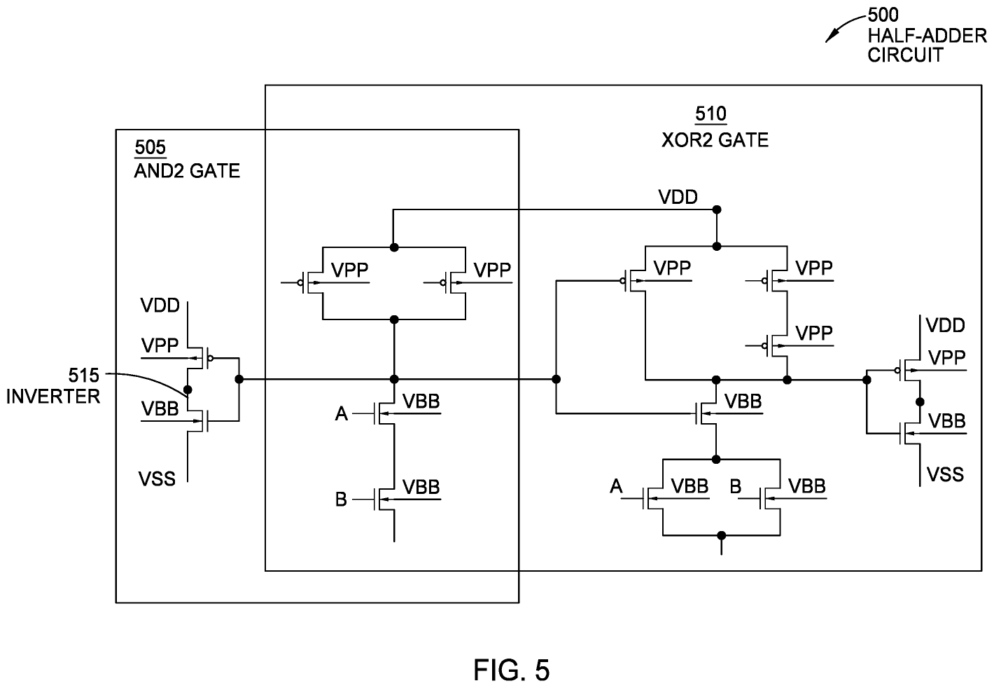

FIG. 5 illustrates a half-adder circuit 500, according to an example. The circuit 500 includes an AND2 gate 505 (which has two inputs) and an XOR2 gate 510 (which has two inputs). In this implementation, the AND2 gate 505 and the XOR2 gate 510 overlap. That is, several of the transistors used to form the AND2 gate 505 are also in the XOR2 gate 510. More specifically, the transistors in the AND2 gate 505 are within the XOR2 gate 510 except for the two transistors forming an inverter 515. As such, the half-adder circuit 500 can be expressed as a combination of the inverter 515 and the XOR2 gate 510.

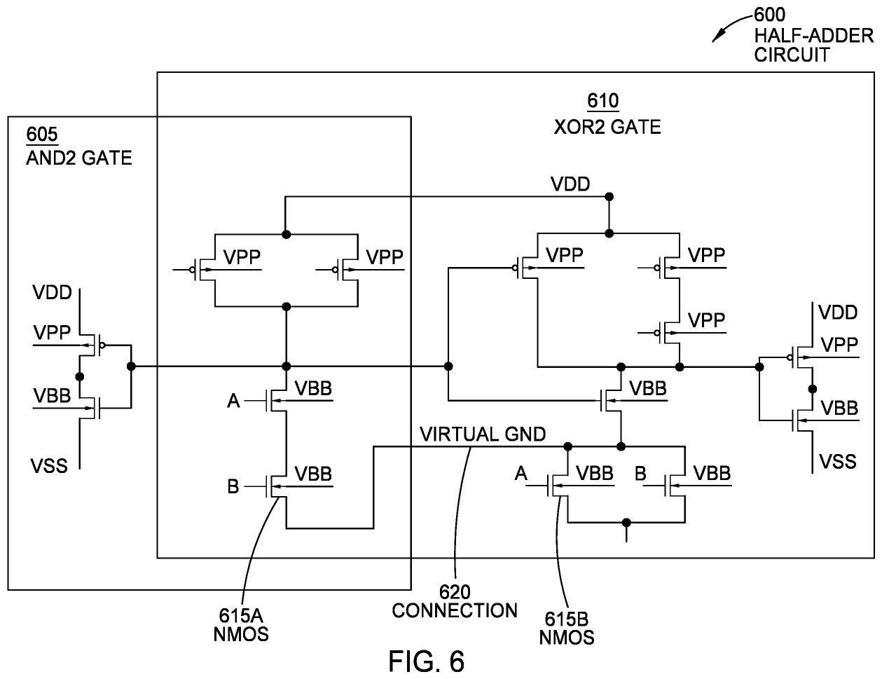

FIG. 6 illustrates a half-adder circuit 600, according to an example. This circuit 600 is also formed using an AND2gate 605 that overlaps with an XOR2 gate 610. However, the circuit 600 differs from the circuit 500 in FIG. 5 in that the source of NMOS 615A is coupled to the drain of NMOS 615B. In contrast, in the half-adder circuit 500 shown in FIG. 5, the source of NMOS 615A is coupled to VSS. However, the voltage VSS is functionally equivalent to the voltage at the drain of NMOS 615B. Thus, the half-adder circuit 600 is modified to include a connection 620 between the source of NMOS 615A and the drain of NMOS 615B which is labeled as virtualGND.

Determining that the voltage at the source of NMOS 615A (e.g., VSS) is functionally equivalent to the voltage at the drain of NMOS 615B can then be used to simplify the layout of the half-adder circuit 600 as discussed below.

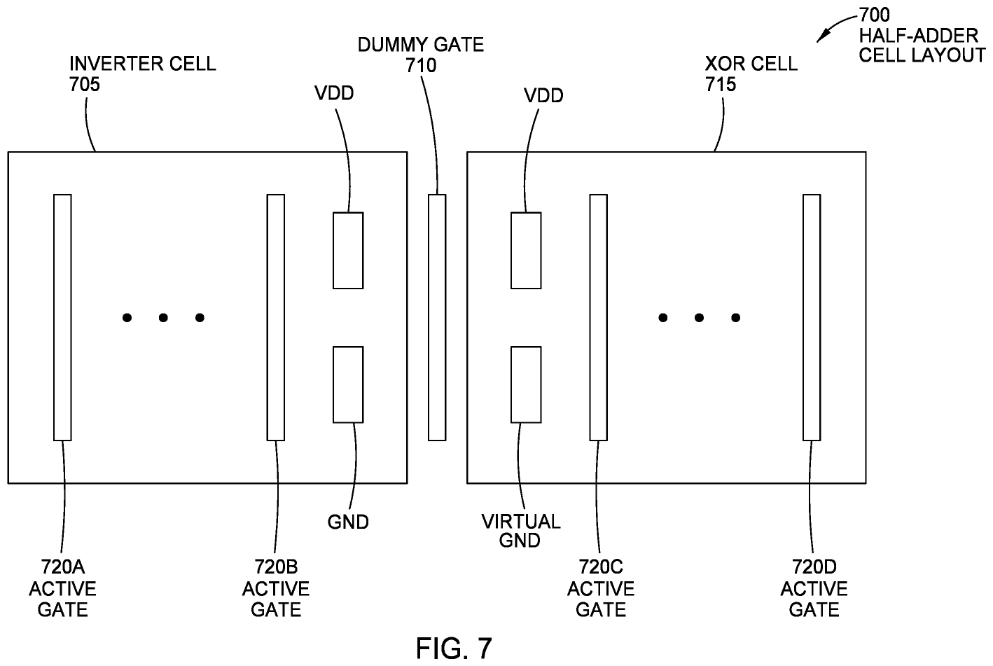

FIG. 7 illustrates a layout 700 of a half-adder cell with a dummy gate 710 between an inverter cell 705 and a XOR cell 715, according to an example. The half-adder cell layout 700 is a physical layout that corresponds to the half-adder circuit 500 circuit in FIG. 5. In this case, the dummy gate 710 is placed between those cells since they are assigned different voltage potentials. That is, the inverter cell 705 includes GND while the XOR cell 715 has virtual GND. However, as mentioned above, these voltage potentials are functionally equivalent.

In one embodiment, the dummy gate 710 may be formed at the same time as the active gates 720A-D (e.g., using the same fabrication steps) but may not be connected to a voltage source (e.g., is inactive). In contrast, the active gates 720 may extend over channels and diffusions areas to form multiple transistors which are interconnected to form the logic of the inverter cell 705 and the XOR cell 715.

In one embodiment, the pitch (e.g., CPP) between the active gates 720 and the dummy gate 710 is fixed. In current technologies, 1 CPP (e.g., the pitch between two adjacent active gates 720, or the pitch between the dummy gate 710 and an adjacent active gate 720) is approximately 48 nm. In some current implementations, the half-adder cell layout 700 may have a 10 CPP width. However, if the dummy gate 710 is removed, this can be reduced to a 9 CPP width.

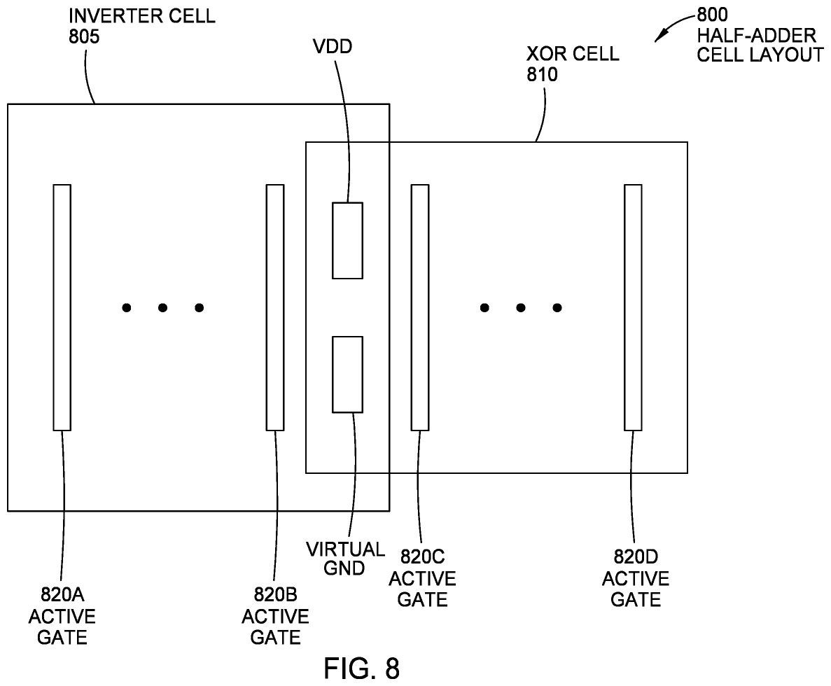

FIG. 8 illustrates a layout 800 of an half-adder cell with overlapping inverter and XOR cells, according to an example. The half-adder cell layout 800 is a physical layout that corresponds to the half-adder circuit 600 circuit in FIG. 6. In that circuit, the source of NMOS 615A is coupled to the drain of NMOS 615B. That is, the half-adder circuit 600 is modified relative to the circuit 500 in FIG. 5 to include a connection 620 between the source of NMOS 615A and the drain of NMOS 615B which is labeled as virtualGND.

This modification of the circuit 600 in FIG. 6 permits the dummy gate to be removed from the half-adder layout 800. That is, the layout 800 includes only active gates 820. That is, the inverter cell 805 overlaps with the XOR cell 810. In this case, the VSS and the VIRTUAL GND are two nets that are shared by both the inverter cells 805 and the XOR cell 810, which causes these cells to overlap. Stated differently, the VSS and VIRTUAL GND are in both the inverter cell 805 and the XOR cell 810, where in FIG. 7 these cells had their own metal contacts.

By removing the dummy cell and sharing the nets, the width of the half-adder layout 800 can be smaller than the layout 700 in FIG. 7. In one example, the layout 800 has only 9 active gates, which means it has a width of 9 CPP instead of the 10 CPP width of the layout 700 in FIG. 7. Thus, by combining the two pairs of nets in FIG. 7 into one pair of nets in FIG. 8, the dummy gate can be removed and the physical layout 800 of the half-adder circuit in the IC can be reduced by 1 CPP. This advantageously saves area in the IC. Thus, regardless of the overall width of the half-adder circuit layout, the embodiments herein can be used to reduce the width of the layout by at least 1 CPP by removing a dummy gate between (or in) cells in the layout.

Although not shown, the half-adder cell layout 800 can also be implemented in an IC (like in FIG. 3). This IC can be part of a system (e.g., a package) that includes other ICs and devices.

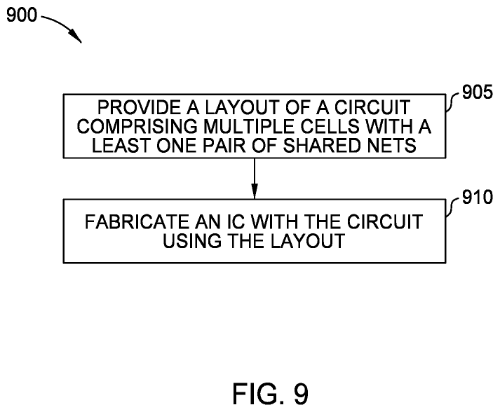

FIG. 9 is a method 900 for fabricating an integrated circuit, according to an example. At block 905, a layout of a circuit is provided where that circuit comprises multiple cells with at least one shared net. For example, a designer may use a software tool to generate a layout for an integrated circuit. In one embodiment, electronic design automation (EDA) can be used to design and analyze the layout.

Examples of the circuit could be an XOR, XNOR, or half-adder circuit. For example, FIG. 3 illustrates the layout 300 of an XOR circuit where a NOR cell 310 shares a pair of nets (i.e., NET VIRTUAL GND and GND) with the AOI cell 315. As another example, FIG. 4 illustrates the layout 400 of an XNOR circuit where a NAND cell 405 shares a pair of nets (i.e., NET VIRTUAL GND and GND) with the OAI cell 410. As another example, FIG. 8 illustrates the layout 800 of a half-adder circuit where an inverter cell 805 shares a pair of nets (i.e., GND and VIRTUAL GND) with the XOR cell 810. However, the embodiments herein are not limited to these three circuits, but can apply to any layout where nets in two different cells are conditionally functionally equivalent. Recognizing this situation can mean the dummy gate which is traditionally placed between (or in) cells can be removed, thereby reducing the size of the circuit.

At block 910, an IC is fabricated to include the circuit using the layout. IC fabrication can include a plurality of fabrication steps that use a series of masks to pattern the circuit in the IC. The fabrication steps can include photolithographic and/or physio-chemical process steps. Moreover, the IC can be fabricated as part of a larger wafer that includes a plurality of ICs.

Because the dummy gate between the two cells in the circuit is removed, the circuit may have a smaller footprint in the IC. If this circuit is used frequently in the IC, this can free up significant real estate that can be used by other circuits or to reduce the overall size of the IC.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the users computer, as a stand-alone software package, partly on the users computer and partly on a remote computer or entirely on the remote computer or server. In the latter scenario, the remote computer may be connected to the users computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. An integrated circuit (IC), comprising:
at least one of an XOR or XNOR circuit comprising at least two cells,
wherein the two cells overlap such that each of the two cells share at least one net,
wherein there is no dummy gate between or in either of the two cells.

2. The IC of claim 1, wherein the two cells share at least two nets.

3. The IC of claim 1, wherein each of the at least two cells comprises a plurality of active gates, wherein there is no dummy gate between or in either of the at least two cells, wherein a pitch between two adjacent active gates is less than 50 nm.

4. The IC of claim 3, wherein the two cells are in a row, wherein the row includes at least four metal tracks that extend perpendicular to the plurality of active gates, wherein at least one of the plurality of active gates are configured to be coupled to any one of the at least four metal tracks.

5. The IC of claim 1, wherein the IC comprises the XOR circuit, wherein the at least two cells comprise a NOR cell and an AND-OR-INVERTED (AOI) cell that share the at least one net.

6. The IC of claim 5, wherein a combined width of the NOR cell and the AOI cell is 6 contacted poly pitch (CPP).

7. The IC of claim 1, wherein the IC comprises the XNOR circuit, wherein the at least two cells comprise a NAND cell and an OR-AND-INVERTED (OAI) cell that share the at least one net.

8. The IC of claim 7, wherein a combined width of the NAND cell and the OAI cell is 6 CPP.

9. The IC of claim 1, wherein the at least one net net is a virtual VDD.

10. The IC of claim 1, wherein the at least two cells are formed using a 3 nm process or smaller.

11. A system, comprising:
an IC, comprising:
at least one of an XOR or XNOR circuit comprising at least two cells,
wherein the at least two cells overlap,
wherein there is no dummy gate between or in either of the two cells;
and
a memory communicatively coupled to the IC.

12. The system of claim 11, wherein the at least two cells overlap by sharing at least one net.

13. The system of claim 11, wherein each of the at least two cells comprises a plurality of active gates, wherein a pitch between two adjacent active gates is less than 50 nm.

14. The system of claim 11, wherein the system comprises the XOR circuit, wherein the at least two cells comprise a NOR cell and an AOI cell where there is no dummy gate between or in the NOR cell or the AOI cell.

15. The system of claim 14, wherein a combined width of the NOR cell and the AOI cell is 6 CPP, wherein the NOR cell and the AOI cell are formed using a 3 nm process or smaller.

16. The system of claim 11, wherein the system comprises the XNOR circuit, wherein the at least two cells comprise a NAND cell and an OAI cell where there is no dummy gate between or in the NAND cell or the OAI cell.

17. The system of claim 16, wherein a combined width of the NAND cell and the OAI cell is 6 CPP, wherein the NAND cell and the OAI cell are formed using a 3 nm process or smaller.

18. A method comprising:
providing a layout of an XOR or XNOR circuit comprising multiple cells with at least one shared net; and
fabricating an IC that includes the XOR or XNOR circuit using the layout and a 3 nm process or smaller.

19. The method of claim 18, wherein the multiple cells share at least two nets.

20. The method of claim 18, wherein each of the multiple cells comprises a plurality of active gates, wherein there is no dummy gate between or in the multiple cells.
